(19) United States
(12) Patent Application Publication
(10) Pub. No.: US 2025/0086332 A1
(43) Pub. Date: Mar. 13, 2025

(54) SYSTEM AND METHOD FOR DESIGNING AND BUILDING CUSTOM FURNITURE USING ARTIFICIAL INTELLIGENCE

(71) Applicant: Autonomous Robotics Technology, Austin, TX (US)

(72) Inventor: Craig Nehrkorn, Austin, TX (US)

(21) Appl. No.: 18/818,554

(22) Filed: Aug. 28, 2024

Related U.S. Application Data
(60) Provisional application No. 63/579,281, filed on Aug. 28, 2023.

(51) Int. Cl. G06F 30/12

(52) U.S. Cl. CPC G06F 30/12

(57) ABSTRACT

A system configured to enable custom manufacturing equipment to be produced. The system may utilize artificial intelligence (AI), such as generative AI, that is configured to generate custom furniture. In an embodiment, the system may be configured to capture images of a room and a space within the room to determine measurements in which the custom furniture is to be positioned. The system may further be configured to capture an image and determine size and shape of a user who is to use the furniture and incorporate measurements of the user as part of generating the custom furniture. Materials of the custom furniture and structural analysis may also be performed as part of the design. In an embodiment, joints, including custom joints, may be created based on the type of material(s) of the custom furniture and uses (e.g., number of people or weight to be supported).

### CROSS REFERENCE TO RELATED APPLICATION

This application claims the benefit of U.S. Provisional Application No. 63/579,281, filed Aug. 28, 2023, the contents of which are hereby incorporated by reference in their entirety.

### BACKGROUND

Furniture design is typically performed and then mass produced by furniture manufacturers for shoppers to purchase. Often time, furniture is purchased from showroom floors. Larger showroom floors will have fairly standard furniture designs that are not overly creative because the furniture is meant to have a broad consumer appeal that will fit into an average home. More creative designs of furniture may be found in furniture boutiques, but even those furniture designs are somewhat standardized because the designers do not have specific design criteria for potential consumers. Such specific design criteria may include size of a room and space in which the furniture is to be positioned, room color, other furniture, and so on. As such, even though the more creatively designed furniture may be more artistic than traditional furniture, such designs are still inherently limited.

For wealthier people who are able to afford furniture designers, those designers may provide for specialized and customized furniture. While that level of customized furniture is truly unique and can be very beneficial to living environment for an owner of the furniture, most customized furniture by a furniture designer is beyond the means of most people.

Artificial intelligence (AI) has recently evolved to provide for generative AI. Generative AI offers the ability to people who are not creative to gain the ability to create images, writings, and physical designs of a wide range of things. One such use of generative AI is to create furniture designs. While the creation of furniture designs using generative AI is possible, generative AI has not yet advanced to solve real-world physical problems in ways in which human designer are trained. Manufacturing can be challenging, and depending on materials and other real-world issues, tradeoffs that have to be considered for fabricating customized furniture have to be resolved in ways that are beyond generative AI capabilities. As such, there is a need for a system that integrates generative AI as a component of a customized furniture design system that can be used by ordinary people of ordinary means and produce customized furniture at affordable prices.

### BRIEF SUMMARY

To provide for custom furniture at conventional furniture prices, the principles provided herein utilize an artificial intelligence (AI) engine, such as a generative AI engine, to design custom furniture. The system may be configured to determine and generate a prompt inclusive of a number of parameters based on certain inputs by a user, such as room dimensions, space within a room in which the custom furniture is to fit, motif of existing furniture or as selected by a user, space between the custom furniture and other furniture or fixture in the room, rugs, ceiling fan position, and so on. In an embodiment the system may be configured to capture an image of one or more people who may use the furniture to determine size of the person(s) so that the custom furniture is dimensioned for those persons. For example, the custom furniture may have height, length, cushion density, etc., based on the dimensions of the persons. Color and other aesthetic features may be automatically, semi-automatically, or manually selectable using the system. The system may further be configured to select conventional joints or create custom joints for the custom furniture. Moreover, the system may be configured to perform structural analysis and, depending on the results of the structural analysis, alter the custom furniture to ensure that the custom furniture is sufficiently strong for intended use. In an embodiment, a simulation that may perform Monte Carlo testing may be used to ensure structural integrity. The system may be configured, for example, to perform structural analysis with different material types. In an embodiment, cost of the materials may be utilized in design the custom furniture, including creating a design as a function of types of machinery available to vendor(s) who are to produce one or more features of the custom furniture.

One embodiment of a computer-implemented method of designing custom furniture may include receiving a scanned image of a room in which custom furniture is to be positioned. Size of space in which the custom furniture is to be positioned may be calculated. Maximum external dimensions in which the custom furniture is to be contained based on the size of the space in which the custom furniture is to be positioned may also be calculated. At least one physical parameter of the custom furniture may be received via a user interface. An artificial intelligence engine may be caused to generate at least one piece of the custom furniture in response to submitting a prompt including the at least one physical parameter of the piece(s) of the custom furniture and maximum external dimensions. In response to receiving a selection of the generated piece(s) of the custom furniture by a user, a simulation may be executed to define at least one structural member of the at least one piece of custom furniture that satisfies the at least one physical parameter. A system that performed the process may further be provided, where the system may be located on a computer network, such as the Internet, accessible via a mobile app, website, or otherwise. In an embodiment, after the custom furniture is generated, a user interface may be configured to display the custom furniture using virtual reality (VR), augmented reality (AR), or graphically on an electronic display of a mobile device, such as a smartphone, tablet, AR/VR headset, or otherwise. In an embodiment, the system may be configured to enable the user to graphically manipulate the size, shape, weight, or otherwise using the user interface. For example, if an AR/VR headset or other electronic device, the user may virtually manipulate the custom furniture with his or her fingers and the system may automatically made adjustments and perform the structural analysis to ensure structural integrity after the adjustment(s) by the user.

### BRIEF DESCRIPTION OF THE DRAWINGS

Illustrative embodiments of the present invention are described in detail below with reference to the attached drawing figures, which are incorporated by reference herein and wherein:

FIGS. 1A-1E are images of illustrative custom furniture produced using generative AI;

FIG. 2 is an image of an illustrative room in which various features are shown;

FIG. 3 is an image of a scene in which a user utilizing an app that is a front-end of a custom design furniture system that utilizes an artificial intelligence system or engine;

FIG. 4 is an illustration of an illustrative system in which a system operator may execute a server configured to operate a custom furniture AI design system;

FIG. 5 is a flow diagram of an illustrative process for producing custom furniture;

FIG. 6 is a illustration of an illustrative user interface (UI) for interacting with a furniture artificial intelligence design system; and

FIG. 7 is a block diagram of illustrative modules of software for supporting the furniture design system provided in FIG. 4.

### DETAILED DESCRIPTION OF THE DRAWINGS

Creating furniture that meets people's tastes can be challenging. Many people want to have more interesting furniture than standard showroom furniture that is often generic and not interesting. Custom furniture designed by a furniture designer is typically expensive and out-of-reach financially by most people. With the creation of generative artificial intelligence, such as Dall-E2, MidJourney, or other generative AI systems, the ability to create custom furniture or other physical devices that would typically be created by a trained furniture designer or artist is now possible at significantly lower cost. The problem, however, is that most generative AI systems are artistic, but do not have the ability to actually realize or engineer the structures that are generated. For example, structures designed for human use are to have certain load bearing features, such as leg strength and dimensions and different construction material types, such as wood, metal, glass, and/or combination thereof that have different structural properties.

Moreover, custom furniture is designed for a particular space within a room, and the custom furniture is to be properly sized within the space. Because the room may have other furniture, rugs, wall sockets, lighting, etc., the custom furniture should be designed to properly fit the space within the room. The custom furniture may be formed on a single or multiple pieces (e.g., sectional couch, chair with ottoman, etc.). As such, to simplify the process of designing the custom furniture, a formal process that includes measuring a room and/or space within a room in which the custom furniture is to be positioned may be performed prior to further design considerations, as provided hereinbelow.

Still yet, custom furniture may be designed for human ergonomics. In accordance with the principles described herein, the custom furniture may be designs for the size and shape of particular people (e.g., a family) that is to use the furniture. If, for example, parents of a family are tall, heavy, short, light, then the custom furniture (e.g., bed, chairs, couches, etc.), and the custom furniture may be specially sized and configured based on the body sizes and shapes. More specifically, if a father is tall and heavy, then the depth and height of a chair or couch along with cushions respectively higher and denser, and if a mother is shorter and lighter, then the furniture may have the depth and height of the chair along with cushions respectively shorter and less dense.

As such, to simplify the process of designing the custom furniture, a formal process that includes measuring a person's body size (e.g., height, width, inseam, torso length, etc.) along with enabling the person to enter weight, favorite color, etc. may be performed prior to further design considerations, as provided hereinbelow.

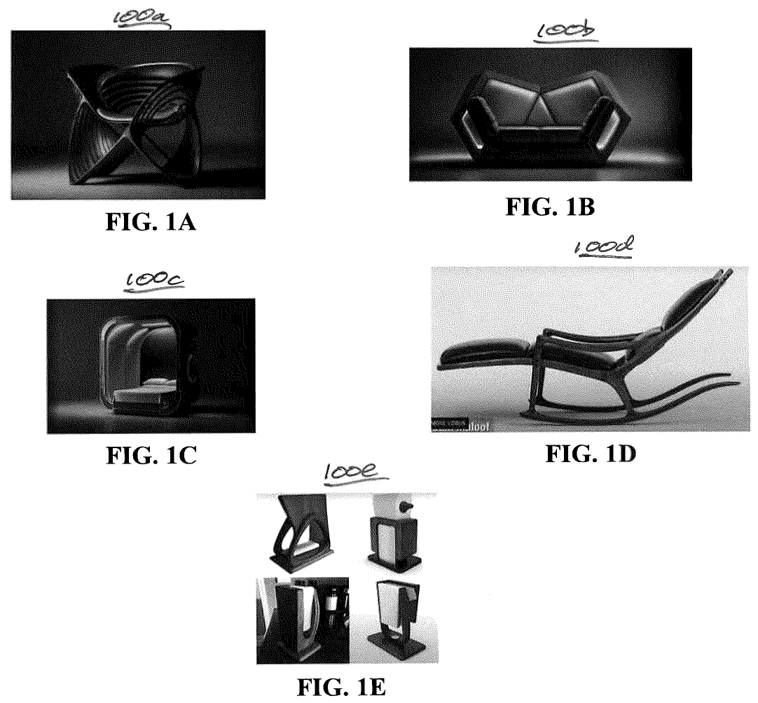

With regard to FIGS. 1A-1E, images of illustrative custom furniture 100a-100e (collectively 100) produced using generative AI are shown. In designing the custom furniture 100, certain information may be submitted in a prompt to the generative AI system to generate the custom furniture 100. For example, dimensions of a room through use of a scanned image and space within the room in which the custom furniture 100 is to be positioned may be submitted to the generative AI system. Certain information, such as number of people to be supported by the custom furniture, style of the custom furniture, motif of the custom furniture, weight of the custom furniture, price of the custom furniture, and so forth may be submitted. For each of the different parameters, ranges may be submitted, where the range may have a maximum value (e.g., maximum price, maximum weight, maximum dimensions, and so forth).

### 1. Scan the Room

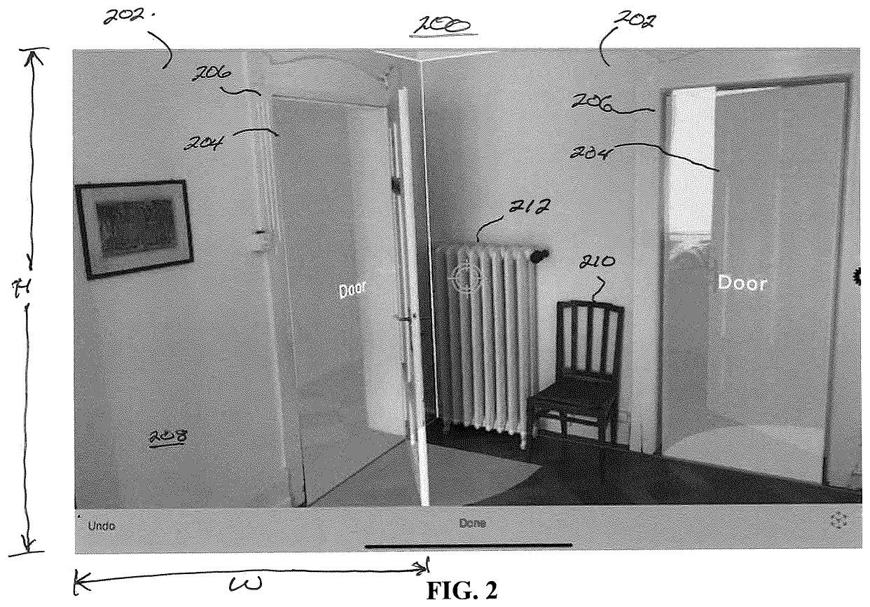

With regard to FIG. 2, an image of an illustrative room 200 in which various features, such as walls 202, doors 204, door frames 206, etc., are shown. In operation, a user may use a mobile device, such as a smart phone, that is executing a mobile app, as understood in the art. In an embodiment, the mobile app may be configured to capture an image of the room 200 and automatically identify various features (e.g., door) within the room 200. The app may be configured to determine dimensions of the room 200, including height H, width W, and so forth of the room 200, but may further be able to determine dimensions of spaces within the room 200, such as dimensions of wall space 208 against which a piece of custom furniture may be positioned. In addition, if other objects, such as furniture 210, doors 204, windows (not shown), electrical outlets (not shown), dressers with drawers (not shown), carpets or rugs (not shown), radiators 212, or otherwise, are located within the room 200, the app may be configured to determine locations and distances of the various objects such that a determination may be made as to maximum size of a custom piece of furniture may be positioned and still provide adequate distance from the other objects, such as furniture, windows, radiators, etc., without the custom furniture contacting or otherwise blocking the other objects. Moreover, the app may factor into the maximum size of the custom furniture to enable a safe walkway between the custom furniture and other objects within the room 200.

In an embodiment, the mobile device executing the app may be configured to scan and determine dimensions of one or more people who may use the furniture. For example, if a family has multiple people, then the app may used to scan multiple people and determine physical characteristics of the people so that the custom furniture or individual pieces thereof may be specifically designed for one or more of the individuals. If, for example, the custom furniture is configured to be dynamic (e.g., capable of being physically altered using electromechanics or other physical alterations), then the dimensions may allow for the custom furniture to automatically determine which person is about to sit or lay on the furniture and make dynamic adjustments. If a table has multiple chairs, for example, then each chair may be custom fit for each of the individuals scanned. The app may be configured to utilize the measurements, optionally including weight that is determined by the app and/or submitted by a user, to be factored into the custom furniture design in addition to the sizing, materials, etc., determined by the app based on room size and other room-dependent features, as previously described. Moreover, the app may be configured to capture styles of furniture that already exist in a room (or throughout the house) and automatically select a style of furniture that is in the same or similar motif, if so desired by the user.

In an embodiment, a measuring system may be provided with a mobile app that is used in part to design custom furniture. The process may include launching the mobile app and scanning the room and space where furniture is to be placed. In scanning the room and space, the mobile app may utilize a camera and any measurement features, such as LiDAR or other remote sensing technology for detecting range.

In an embodiment, a data repository may be configured to support the app, which may be a mobile app, cloud-based app, or otherwise, by enabling the app to inventory and classify currently available design motif. The app may be configured to measure the size of the space where the custom furniture is to be placed. Measurements may include height of a wall against or proximate to the custom furniture is to be positioned, height of adjacent furniture (e.g., existing or furniture to be co-located), depth of the room, depth of adjacent furniture, width of the space, width with buffer space deducted so furniture does not touch, rub, or overlap, and space relative to other objects/structures to ensure sufficient walking space.

In an embodiment, the app may suggest maximum external dimensions of the custom furniture space claim and angle of orientation. The app may be configured to identify and note any conflicts with other objects, such as surrounding furniture, outlets, windows, rugs, lighting, and fans. In an embodiment, the app may be configured to prompt a user with questions or parameters, such as, will this furniture need wheels, be able slide, need handles to move, need to stay within a certain weight range?

### 2. Design the Furniture Using AI

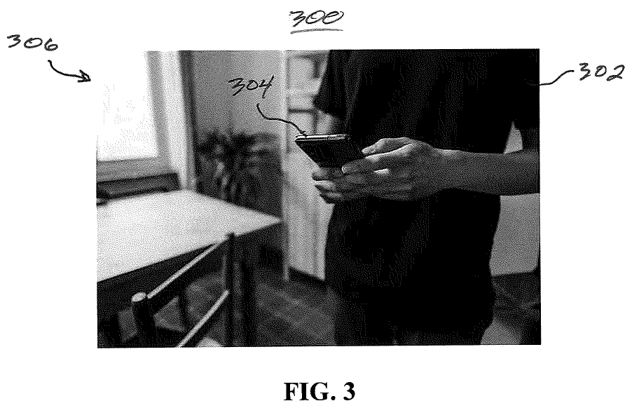

With regard to FIG. 3, an image of a scene 300 in which user 302 holding a computing device 304, in this case a smart phone, utilizing an app that is a front-end of a custom design furniture system that utilizes a generative artificial intelligence (AI) system or engine is shown. The user 302 of FIG. 3 may have performed a scan of a room 306, and may enter information that the system is to use and generating a prompt to be submitted to the AI engine. The information may include motif, size, weight, style, number of people to support, weight of people to be supported, or otherwise, as further described herein.

The app may be configured in a number of ways, but may ultimately be configured to provide ease of use for non-technical users and provide many features in graphical representations. The user interface may provide simple messages, such as “scan the room from a central location by pressing the ‘scan room’ button and turn slowly.” After the scan of the room is completed, a message of, “tap or circle a space in the image at which the custom furniture is to be positioned.” The circle may be at a location of a floor and a user may draw lines (e.g., circle, rectangle, or other geometric or non-geometric shape), for example, on a floor defining approximate boundaries in which the user desires to place the furniture.

The app may be configured to develop restrictions on how open source generative or non-generative AI tools may be used to create images, and those immediate and long term restrictions may be cataloged. The restrictions may include restrictions for customizing etching and painting of wooden furniture, which may include 2D, maximum size of the image, maximum resolution of the image, the maximum granularity of the image, color palette restrictions, paint types, etc. The app may be configured to accept user inputs in the form of voice or text commands or prompts to local engine of the app, which may perform a verification or reformatting of the prompt prior to submitting the prompt to a 3D AI drawing program along with a series of user selections and confirmations. It should be understood that a non-app solution, such as a cloud-based application with a user interface accessible via a browser or other software platform may be provided.

The AI engine may be a generative AI engine, such as OpenAI or MidJourney, may support three methods of image generation:
(i) Creating images from scratch based on a text or voice prompt;
(ii) Creating edits of an existing image based on a new text or voice prompt; and
(iii) Creating variations of an existing image or concept.

An output from submission of the command or prompt in the app may include external furniture dimensions in a graphical format, such as a 3D CAD file format—block and/or mesh, to enable display of the custom furniture (e.g., one or more custom furniture pieces) on a user interface, such as on a scanned image or using virtual reality so that the user may see the custom furniture in the actual room in the actual space on a mobile device. As understood, as a user points a camera in the room and when the selected space in which the custom furniture is to be positioned is identified by the mobile app, then an image of the custom furniture (e.g., solid and/or mesh) may be displayed on an electronic display of the mobile device. In an embodiment, measurements may be displayed on the image of the custom furniture, such as along edge(s) of the image of the custom furniture.

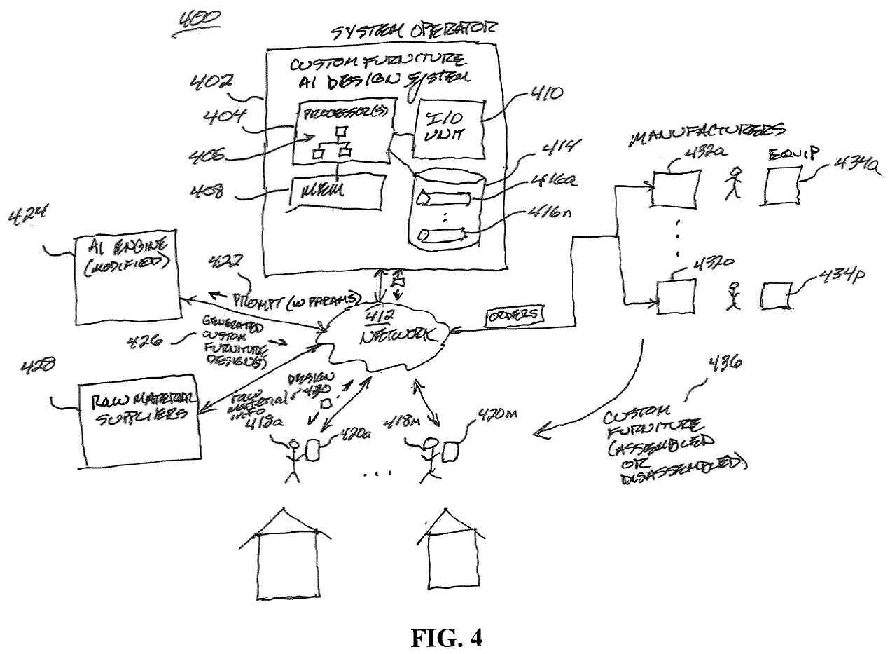

With regard to FIG. 4, an illustration of an illustrative network environment 400 in which a system operator may execute a server configured to operate a custom furniture AI design system is shown. The custom furniture AI system may be a generative AI system or otherwise. The server 402 may include one or more processors 404 that execute software 406 that is used to collect and manage information associated with users, furniture materials, craftsmen, other suppliers, equipment of craftsmen and suppliers, and/or otherwise. The server 402 may further include a non-transitory memory 408, input/output (I/O) unit 410 configured to communicate data over one or more communications networks 412, and storage unit 414 configured to store one or more data repositories 416a-416n (collectively 416). The data repositories may include information associated with users, craftsmen and respective manufacturing equipment, materials, pricing of materials, pricing of craftsmen, different furniture motifs, and a variety of other information associated with generating furniture, including forming proper prompts.

The server 402 may be in communication with the network(s) 412 to enable users 418a-418m (collectively 418) to utilize their mobile devices (e.g., phones, tablets, laptops, etc.) 420a-420m (collectively 420) to communicate with the server 402. As previously described, the mobile devices 420 may be configured to execute a mobile app and/or interface to a remotely executed application or system that enables the customer to capture images of a room and have the dimensions of the room automatically determined. Moreover, the mobile app may enable a user to select an area or space within a room where the custom furniture is to be located. The mobile app and/or remotely executed application or system may be configured to determine dimensions of the space along with maximum dimensions for custom furniture of a certain type that may fit within the space while accounting for other furniture, windows, outlets, walkways, radiators, etc., located at or near the space selected by the user. In enabling the user to select the space, the user may tap or circle an area in which the user intends to place the custom furniture. In an embodiment, other graphical tools, such as boxes, circles, ovals, or other graphical features may be utilized to assist the user in defining the space in which the user intends to place the custom furniture.

Once the user has submitted information about the custom furniture he or she wishes to have produced, along with dimensions of space in which the furniture is to be limited, the system may be configured to submit a prompt inclusive of the information (e.g., instructions) 422 to a generative AI engine 424. The generative AI engine 424 may be configured to generate custom furniture designs 426 that may be communicated back to the user. In an embodiment, the generative AI engine may be trained for the specific purpose of furniture design in accordance with the principles described herein. In an alternative embodiment, the app may be configured to support a direct submission to the AI engine 422. Once the user receives back the custom furniture design(s) 424, such as shown in FIGS. 1A-1E, the mobile app may be configured to enable the user to make adjustments to the custom furniture designs generated by the generative AI engine 424. Such corrections may include, but are not limited to, shapes, motifs, angles, sizes, or otherwise. Once the user is satisfied with the design, the user may select a “select custom furniture” button.

### 3. Post AI Modifications

In an embodiment, users may edit the custom furniture design and control costs through different material quality selections, such as softwood vs hardwood, steel vs aluminum, etc. To support such cost control through different material quality selections, a catalog (e.g., local and/or cloud stored) of raw material and corresponding prices may be available to the app.

A number of pre- or post-AI submission questions related to features to be included with the custom furniture may be provided. For example, “will this furniture need wheels?,” “should this furniture be able to slide?,” “does this furniture need handles to be moved?,” “does this furniture need to stay within a certain weight range?” Furthermore, “how does this furniture need to be disassembled to ensure it is shippable?,” how does this furniture need to be disassembled to ensure it is manufacturable?,” “how does the furniture need to be disassembled to ensure it is assemblable?,” etc. It should be understood that additional and/or alternative questions may be requested from the user. It should further be understood that the questions may be preset and that answers to each question may result in one or more follow-up questions for the user

In an embodiment, the system may be configured to support 3D CAD file disassembly and/or assembly algorithms that start by creating small boxes from the largest box in which furniture may be sized. The app may be configured with a script or other software that supports a shipping cost calculator and/or integrates into an existing calculator that uses dimensional weights and round trip shipping addresses. In an embodiment, the system may be configured to access raw material information available from raw material suppliers 428 to supply raw material information 430 to tradesmen or manufacturers 432a-430o (collectively 430) who may be capable and/or available to produce the custom furniture if a determination about certain raw materials as to pricing and/or quality meeting specifications for production of the further designed by the generative AI engine 424. The ability to optimize logistics and tradesman job assignments may simplify user or customer experience and provide a profit margin lever for a system operator (i.e., company providing the app for the custom furniture).

In response to the user selecting a “select custom furniture” button that indicates that the user satisfied with the custom furniture design, the processor(s) 404 may be configured to execute the software 406 that may be configured to perform a simulation or structural design function. The simulation or structural design function may be configured to perform a structural analysis of the furniture to ensure safety, strength, comfort, ergonomic alignment, padding, joint configurations, dimensions, etc., based on materials that the system and/or user selects in producing the custom furniture. For example, the user may elect to enable the system to determine the material (e.g., wood, aluminum, steel, etc.) to be used in fabrication of the custom furniture, and the system may use the simulation to determine sizing, pricing, dimensions, etc. of the day materials and producing the custom furniture. The simulation may generate the custom furniture using one or more of the available different materials based on availability and capability of the manufacturers 432. In an embodiment, the user may select the different materials to be used in fabricating the custom furniture that was provided by the generative AI engine 424, and the simulation may update suppliers, manufacturers, costs, etc.

The simulation may also have the ability to identify potential craftsmen or manufacturers 432 that have equipment 434a-434p (collectively 434) capable of working with the selected materials along with determining timing for production based on availability of the selected craftsmen 432. The system 402 may provide the users with a user interface with user design prompt(s) and information fields that indicates the custom furniture and different materials along with different pricing, scheduling, weight, etc., for each of the various different materials that may be utilized in producing the custom furniture. In addition to determining the materials that are capable of supporting weight, number of people to simultaneously sit or stand on the furniture, etc., the simulation may further be configured to design or otherwise select joints of the furniture that are capable of supporting usage of the furniture. The usage may include a number of people to reside on the furniture at any given time, anticipated amount of movement of the furniture, whether the custom furniture has wheels, whether the furniture has handles, etc. Once built, custom furniture 436 may be shipped to the respective users 418.

### 4. Structural Analysis

A hard-coded solution may be used to determine the structural requirements of the custom furniture. These structural requirements may include the amount of weight the furniture is to support, strength requirements for lifting, strength of joints between large surfaces where pressure is anticipated to be applied by carrying, stacking, leaning, or pulling. The user may be asked how many people the furniture is intended to support and a maximum amount of weight to be supported.

In an embodiment, structural simulations may be performed on the rough geometry of the custom furniture to determine what material type may work for each of the major component areas and joint solutions that may be proprietary or custom (or selected off-the-shelf or conventional joint solutions) to support the custom furniture. For example, if the legs of a chair are to support a certain weight, but are restricted in their max cross sectional area and minimum height, a model of the material strength needs of the legs may be performed and material options may be determined or selected. In addition, a structural analysis and material selection may be performed to select joint solutions. Depending on the complexity, 3D printed metal or a universal set of joint solutions may be developed and may be produced for the joints. In an embodiment, a jobs platform for engaging contractors who are able to produce different parts of the furniture may be provided.

### 5. Manufacturing

After the simulation has been executed and the furniture is processed by the simulator to ensure that each of the structural members are sufficiently and appropriately sized, the system may communicate orders to manufacturers to produce the custom furniture or furniture parts. After production, the manufacturers may ship the custom furniture assembled or disassembled to the customers (or retailer, designer, or other establishment) to be provided to the customer for use.

Because of the nature of custom furniture, a wide range of machinery and manufacturers, including tradesmen, is often utilized. In an embodiment, the system may enable independent tradesmen to register to produce some or all components of the customer furniture. As part of the registration, the independent (or non-independent) tradesmen may register machine makes and models so the system knows what kinds of jobs each of the registered tradesmen can perform. The machine types may provide the system with information as to what file types the registered tradesmen need to perform CNC, lasercut, waterjet, 3D printed, and other machine jobs. Some jobs could be hand craftsman type jobs. A workflow diagram may be used to show all data transformation needs, file types, and identify QA checkpoints.

Material types, raw form and fabrication options may include:
a. Wood (e.g., Plywood, Posts, Structural, Blocks, 3D printed)
b. Glass (e.g., Sheets)
c. Metal (e.g., Sheets, Blocks, 3D printed)
d. Plastic
e. Fabric
f. Cushions

### Custom Furniture System Example

An example of a process using the system described to produce custom furniture using laser etching and custom painted wood herein may include: Establish a webpage for kits or fully assembled furniture that can be customized through a custom furniture design service of the system. An AI canvas may be constricted to the workable dimensions of wood and size limitations of etching and painting machines for producing the custom furniture.

### Sample Use Cases & User Journeys

The system and processes provided herein may be configured to:
A. Restore old furniture
1) convert a basic ugly wooden bar into something new by adding a new surface, rail or backing,
(2) extend an existing design to fill in missing design elements or increase in size,
B. Create new furniture concepts
C. Blend two furniture concepts
(a) submit a picture of two existing pieces of furniture and let AI merge the pieces of furniture.

The system may be configured to enable an operator to (i) create unfinished furniture kits to the degree it can be cost effectively mass produced, such as a furniture kits.

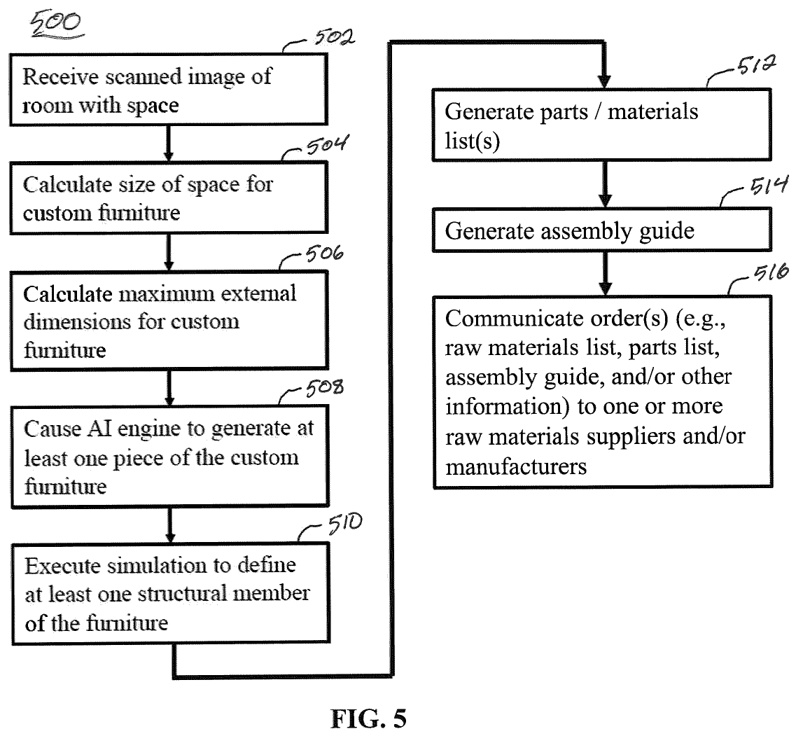

With regard to FIG. 5, a flow diagram of an illustrative process 500 for producing custom furniture is shown. The process 500 may start at step 502 by receiving a scanned image of a room with space in which the custom furniture is to be positioned. Size of the space for the custom furniture to be positioned may be calculated at step 504. The location of the space may be selected by a user of a mobile app that is used to scan the room, circle, or otherwise interact with a user interface on which the scanned image of the room is displayed. Maximum exterior dimensions of the custom furniture may be calculated at step 506 by the mobile app. In an alternative embodiment, the mobile app may communicate the images to a remote server for performing some or all of the calculations of the size of the room and space selected by the user. In an embodiment, rather than capturing image of the entire room, an image of the space may be captured in a single image. Alternatively, the user may use a video, panoramic, or other advanced imaging feature of a mobile device. In an embodiment, the user may capture an entire wall or portion thereof and be asked to enter dimensions of features within the image. For example, one feature may be height from four from floor to ceiling if both the floor and ceiling are captured in the image. Alternatively, dimensions of other features or objects within the room may be specified, thereby enabling the app or system to determine other dimensions, such as space along a wall that the custom furniture is to be positioned. If a common feature is identified in the image, the system may automatically identify the common feature, look-up dimensions of the common feature, and automatically perform measurements of other objects or structural features captured in the image.

In an embodiment, an AI engine that generates at least one piece of the custom furniture may be caused to generate the custom furniture at step 508. In causing the AI engine to generate the at least one piece of custom furniture, a prompt inclusive of one or more parameters may be formed and submitted to the AI engine. The parameters may include type of furniture, motif of the furniture, number of people to be positioned on the furniture at any time (e.g., one, two, four, etc.), style of the furniture, weight of the furniture, materials of the furniture, and so forth. Alternatively, the prompt may be open ended to be submitted thereby enabling a user to see what types of furniture the system might consider to be placed in the open space. For example, the user may simply specify “couch,” and the generative AI system may generate a couch that fits within the space. After the custom furniture is generated, the user may have the ability to alter different features of the custom furniture, including but not limited to, size of the furniture, type of furniture, materials of furniture, shape of furniture, and so forth, and resubmit changes via a prompt to the generative AI system for altering the design of the custom furniture.

Thereafter, because the generated custom furniture may simply be a rendition of the type of furniture, a simulation may be executed that assists with designing various features and structural analysis of the custom furniture at step 510. For example, the simulation may utilize different materials, dimensions, and so forth to ensure the structural integrity of the furniture before production thereof. The simulation may utilize a number of different factors, which may include machinery capabilities that may be utilized by craftsmen that are participating in a local or non-local area to produce the custom furniture. For example the simulation may be configured to create different types of joints of different materials that are capable of supporting loads or other weight-bearing situations expected to be applied to the custom furniture. The simulation in performing the structural analysis may utilize a variety of structural analyses, including Monte Carlo processing, in determining structural analysis. For example, the simulation may be configured to perform a maximum structural load failure analysis.

At step 512, a parts list and/or raw materials list of the custom furniture may be generated based on the results of the generative AI engine and simulation. The parts list and raw materials list(s) may be used to provide to raw materials supplier(s) and manufacturer(s) for production of the custom furniture. At step 514, the generative AI engine or system executing furniture assembly software may be configured to generate an assembly guide for the custom furniture. At step 516, order(s) that may include raw materials list, parts, assembly guide, and/or other information may be communicated to one or more raw materials suppliers and/or manufacturers. The communications of the orders and various information to the raw materials, parts list, assembly guide, and/or other information may be communicated in response to the user, manufacturer(s), operator of the system, or otherwise selecting to place the order. In an embodiment, the system may utilize a process that requires multiple parties (e.g., raw materials supplier(s), manufacturer(s), user, and/or operator) to submit an acceptance to avoid the custom furniture being produced and rejected by any of the parties. The list(s) may also include pricing, schedule, and/or any other terms for each of the suppliers, manufacturers, and user or customer for quality, schedule, and/or payment terms.

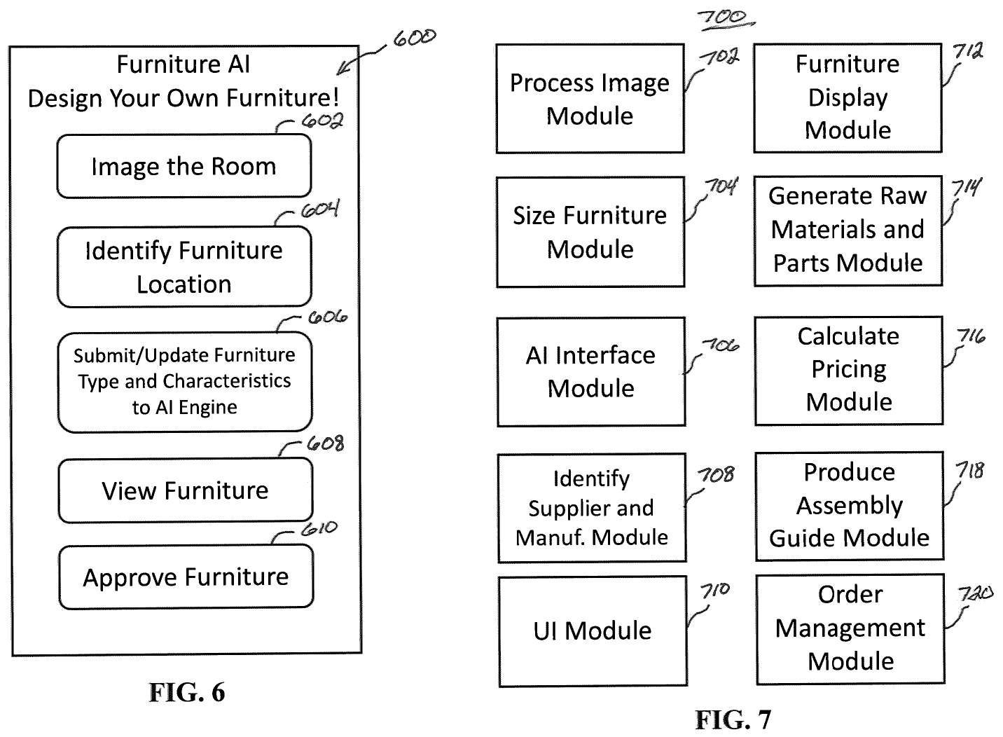

With regard to FIG. 6, a illustration of an illustrative user interface (UI) 600 for interacting with a furniture artificial intelligence design system is shown. The user interface 600 may be that of a mobile app or interface to a remotely operated application (e.g., web server operated system). The UI 600 may include a number of selection buttons that enables a user to perform a number of functions. Button 602 may enable a user to image a room with a camera of a mobile device. The imaging may include using the camera to capture an image, sequence of images, video, etc., that are guided by the user interface (e.g., take photo of walls 1, 2, 3, and 4). Button 604 enables the user to identify location of the furniture being designed to be located. In identifying the location, the user may circle, tap, or otherwise locate the location in which the furniture is to be positioned. In an embodiment, the system may enable a voice submission and (e.g., “place a couch in the space between the lamp and next to the door frame against wall 2”). A user may select button 606 to submit/update furniture type and characteristics to the AI engine.

The submission may be via a prompt field in which the user may type or speak commands to the AI engine with the furniture type and characteristics (e.g., motif, color, shape, weight limits, height limits, etc.). As part of the submission, the user may be prompted with a number of selection fields or be asked questions to help the user define different furniture types and/or characteristics that will better help the generative AI engine generate the custom furniture. Each response may be added to a prompt that is to be submitted to the generative AI engine. If the user wants to change the furniture in any way, the user may update the furniture type and/or characteristics. A button 608 may enable a user to view furniture designed by the AI engine. In response to the furniture being displayed, the user may view the furniture on a user interface. The furniture may include pricing, materials list, parts list, and/or assembly guideline for the user to view. Once satisfied with the designed furniture, the user may select button 610 to approve the furniture. The approval may cause a list generator to generate and/or communicate raw material list(s), parts list(s), and/or assembly guide(s) to selected raw materials producers and/or manufacturer(s) for producing the custom furniture.

Although the UI 600 is shown to include simple buttons 602-610, it should be understood that alternative features may be provided with which a user may interact to perform the various functions. Still yet, rather than being provided buttons for selection, the UI 600 may perform various functions, such as displaying furniture, without the user having to select a button or other feature to view the generated furniture. If the generated furniture (e.g., chair) include multiple versions that may fit within the submitted type and characteristics, then each of the different designed furniture may be displayed or enable the user the swipe or otherwise navigate through many different designs.

With regard to FIG. 7, a block diagram of illustrative modules 700 of software, such as software 406 of FIG. 4, for supporting the furniture design system 402 provided in FIG. 4. A process image module 702 may be configured to process images that may be captured by a user of a room in which custom furniture is to be positioned. The processing may include identifying a motif of the room, size of the room, shape of the room, all the furniture of the room, and so on, so as to be used for creating a prompt for submission to a generative AI system or otherwise assisting a user with furniture selection options. A size furniture module 704 may be configured to size furniture of a particular type selected by user to fit within a space identified by the user. The user, in identifying the space, may interact with a user interface displaying the captured images, such as by circling a space, pointing to a space, or otherwise to identify location within the room in which the furniture is to be positioned. The size furniture module 704 may automatically determine size of the space in which the furniture is to be positioned utilizing measurement tools, such as identifying a known object in the images so as to determine distance or otherwise from the space in which the furniture is to be positioned. Any location sizing function may be utilized in accordance with the principles described herein. In an embodiment, the module 704 may request measurements to be entered by the user.

An AI interface module 706 may support communications with a generative AI platform or system for generating the custom furniture. In an embodiment, the generative AI platform may be a generic generative AI platform or be an AI platform that is trained to specifically to design custom furniture. The AI interface module 706 may provide for a user to enter a prompt that is to be submitted to the generative AI system, and the module 706, when the prompt is complete as indicated by the user (e.g., selectively submitting the prompt via the user interface), may communicate the prompt to the generative AI system for generating the custom furniture. In an embodiment, the AI interface module 706 may additionally include a simulation feature that is used to simulate loads and other aspects of the furniture such that parts, such as legs, brackets, joints (e.g., standard or custom), back rests, etc., that are used to support the furniture and people are sufficiently strong and properly configured (e.g., thickness, proper angles, strong enough connections, etc.). That is, the simulation feature may be used in selecting or creating features of the furniture that satisfies at least one physical parameter (e.g., load).

An identify supplier and manufacturer module 708 may be configured to identify raw good suppliers and manufacturers, who may be local or remote from the user (e.g., within the same town, city, state, country, or otherwise). The raw good suppliers and manufacturers may be identified based on the design of the furniture. As previously described, the raw goods may include materials that are designed specifically to support specific characteristics of the furniture that is submitted by the user platform. The module 708 may be configured to identify suppliers and manufacturers based on availability, capability, skills, pricing, and so forth for designing specific aspects or entirety of the custom furniture.

A user interface (UI) module 710 may be configured to display a user interface with which the user may interact in designing the custom furniture. One such user interface may be that shown in FIG. 6. It should be understood that the user interface may support a wide variety of features and functionality to aid a user in designing custom furniture, as previously described. For example, the user interface may be primarily graphical and use the captured images. Alternatively, the user interface may be configured to use augmented reality in displaying the furniture in the desire space. For example, a generated couch may be virtually positioned in the selected space such that as the user aims the camera of the mobile device at the space from any angle, the generated couch may be positioned in a three-dimensional manner, for example.

A furniture display module 712 may be configured to display furniture that is generated by the generative AI platform. In an embodiment the furniture display module 712 may be configured to display the custom furniture in a space captured in the images at which the furniture is to be placed. The module 712 may alternatively be configured to enable the user to view the furniture in a three-dimensional mode and allow the user to rotate or otherwise view the furniture at any desired angle, thereby enabling the user to determine whether or not he or she likes the furniture features from different angles. The display of the generated furniture may be displayed using virtual reality, as previously described. In an embodiment, the furniture display module 712 may enable the user to tap or otherwise select specific features and change those features in a number of different ways, including changing color, changing pattern, changing shape, changing material, or otherwise altering the furniture either using specific local to the image or updating the prompt submitted to the generative AI platform so as to cause those desired features to be changed using the AI platform as opposed to performing a specific edit. By changing the furniture using the AI platform, materials and or parts may be created by the generative AI platform. In an embodiment, rather than the generative AI platform determining the parts and/or materials, a module independent of the generative AI platform may be used to generate the materials and parts, as described herein below.

A generate raw materials and parts module 714 may be configured to utilize the furniture generated by the generative AI platform and determine specific materials and parts therefrom. In an embodiment, the parts may be determined based on shapes, angles, or otherwise so as to either select from off-the-shelf parts or have custom parts designed utilizing the generative AI platform or otherwise. The custom parts may be defined with specific requirements such that support of particular loads, angles, or otherwise are supported. Additionally, nails, brackets, staples, or otherwise, that may be utilized in assembling the generated furniture. Specific lists of the raw materials and parts may be formed such that the lists may be communicated to one or more suppliers and manufacturers. The lists may include specific details of each of the raw materials and parts, including physical parameters, including size, shape, material, thickness, finish, color, numbers, maximum price, weight, etc.

A calculate pricing module 716 may be configured to utilize the materials and parts lists for calculating price for each of the raw materials and parts along with a total price for assembly of the raw materials and parts based on known or estimated pricing of suppliers and manufacturers. In an embodiment, the module 716 may be configured to issue requests for proposals to one or more of the suppliers and manufacturers to submit estimates for the raw materials, parts, assembly, and shipping of an completed furniture, thereby enabling the user to determine price at any level of the furniture. In an embodiment, the pricing may be performed real-time based on actual or estimated pricing using published or historical information. Alternatively, the module 716 may be configured to operate in a non-real-time basis that is populated upon receipt of pricing from suppliers and/or manufacturers.

A produce assembly guide module 718 may be configured to generate an assembly guide to enable the manufacturer to assemble the furniture designed by the AI platform. In an embodiment, the AI platform may be configured to provide a list of parts along with an assembly guide (e.g., step-by-step process for assembling the furniture). Alternatively, the software may be configured to utilize the design of the custom furniture and create an assembly guide therefrom. The guide may include any number of configurations, such as exploded views, individual part views, connecting mechanisms to connect specific parts, and so forth, so as to enable a manufacturer to assemble and/or disassemble the custom furniture.

In order management module 720 may be configured to track and manage in order of the custom furniture. The modules 720 may be configured to interface with systems of suppliers and manufacturers so as to track current stages of production of raw materials, parts, and/or finished furniture. The module 720 may enable a user to view information associated with the order of the furniture, including receiving notifications of the order. In an embodiment, the module 720 may enable a user to interface with suppliers and manufacturers so as to receive change notices, submit change requests, and otherwise communicate with the suppliers and manufacturers for any number of reasons.

The foregoing method descriptions and the process flow diagrams are provided merely as illustrative examples and are not intended to require or imply that the steps of the various embodiments must be performed in the order presented. As will be appreciated by one of skill in the art, the steps in the foregoing embodiments may be performed in any order. Words such as “then,” “next,” etc. are not intended to limit the order of the steps; these words are simply used to guide the reader through the description of the methods. Although process flow diagrams may describe the operations as a sequential process, many of the operations may be performed in parallel or concurrently. In addition, the order of the operations may be re-arranged. A process may correspond to a method, a function, a procedure, a subroutine, a subprogram, etc. When a process corresponds to a function, its termination may correspond to a return of the function to the calling function or the main function.

The various illustrative logical blocks, modules, circuits, and algorithm steps described in connection with the embodiments disclosed here may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

Embodiments implemented in computer software may be implemented in software, firmware, middleware, microcode, hardware description languages, or any combination thereof. A code segment or machine-executable instructions may represent a procedure, a function, a subprogram, a program, a routine, a subroutine, a module, a software package, a class, or any combination of instructions, data structures, or program statements. A code segment may be coupled to and/or in communication with another code segment or a hardware circuit by passing and/or receiving information, data, arguments, parameters, or memory contents. Information, arguments, parameters, data, etc. may be passed, forwarded, or transmitted via any suitable means including memory sharing, message passing, token passing, network transmission, etc.

The actual software code or specialized control hardware used to implement these systems and methods is not limiting of the invention. Thus, the operation and behavior of the systems and methods were described without reference to the specific software code being understood that software and control hardware can be designed to implement the systems and methods based on the description here.

When implemented in software, the functions may be stored as one or more instructions or code on a non-transitory computer-readable or processor-readable storage medium. The steps of a method or algorithm disclosed here may be embodied in a processor-executable software module which may reside on a computer-readable or processor-readable storage medium. A non-transitory computer-readable or processor-readable media includes both computer storage media and tangible storage media that facilitate transfer of a computer program from one place to another. A non-transitory processor-readable storage media may be any available media that may be accessed by a computer. By way of example, and not limitation, such non-transitory processor-readable media may comprise RAM, ROM, EEPROM, CD-ROM or other optical disk storage, magnetic disk storage or other magnetic storage devices, or any other tangible storage medium that may be used to store desired program code in the form of instructions or data structures and that may be accessed by a computer or processor. Disk and disc, as used here, include compact disc (CD), laser disc, optical disc, digital versatile disc (DVD), floppy disk, and Blu-ray disc where disks usually reproduce data magnetically, while discs reproduce data optically with lasers. Combinations of the above should also be included within the scope of computer-readable media. Additionally, the operations of a method or algorithm may reside as one or any combination or set of codes and/or instructions on a non-transitory processor-readable medium and/or computer-readable medium, which may be incorporated into a computer program product.

The previous description is of a preferred embodiment for implementing the invention, and the scope of the invention should not necessarily be limited by this description. The scope of the present invention is instead defined by the following claims.

What is claimed is:

1. A computer-implemented method of designing custom furniture, comprising:
receiving a scanned image of a room in which custom furniture is to be positioned;
calculating size of space in which the custom furniture is to be positioned;
calculating maximum external dimensions in which the custom furniture is to be contained based on the size of the space in which the custom furniture is to be positioned;
receiving, via a user interface, at least one physical parameter of the custom furniture;
causing an artificial intelligence engine to generate at least one piece of the custom furniture in response to submitting a prompt including the at least one physical parameter of the at least one piece of the custom furniture and maximum external dimensions;
in response to receiving a selection of the generated at least one piece of the custom furniture by a user, executing a simulation to define at least one structural member of the at least one piece of custom furniture that satisfies the at least one physical parameter.

2. The method according to claim 1, wherein calculating size of the space in which the custom furniture is to be positioned includes calculating wall height and width against which the custom furniture is to be positioned.

3. The method according to claim 1, further comprising calculating distance of objects relative to the space in which the custom furniture is to be positioned.

4. The method according to claim 3, wherein calculating distance of objects includes calculating distance of objects relative to the maximum external dimensions of the at least one piece of custom furniture.

5. The method, according to claim 1, further comprising determining conflicts of physical objects relative to the space in which the custom furniture is to be positioned.

6. The method according to claim 5, wherein determining conflict includes determining position of at least one of other furniture, outlets, rugs, fans, HVAC vents, lighting, doors, windows, and radiators.

7. The method according to claim 1, further comprising:
identifying lighting conditions in the space in which the at least one piece of custom furniture is to be positioned; and
responsive to identifying lighting conditions, submitting a parameter to the AI engine inclusive of a physical parameter of at least one piece of custom furniture based on the lighting conditions.

8. The method according to claim 1, wherein receiving price range includes receiving a maximum price of the custom furniture.

9. The method according to claim 1, wherein receiving further includes, receiving at least one motif of the custom furniture to be generated.

10. The method according to claim 1, further comprising submitting a weight range of the at least one piece of custom furniture.

11. The method according to claim 1,
wherein executing the simulation includes selecting one or more materials and one or more dimensions of the structural member; and
further comprising establishing constraints as a function of available equipment to be used in producing the custom furniture.

12. The method according to claim 1, wherein executing the simulation includes determining configuration of at least one joint of the at least one piece of custom furniture.

13. The method according to claim 1, further comprising displaying, on an electronic display, a graphical representation of the at least one piece of custom furniture on the scanned image of the room.

14. The method according to claim 1, wherein receiving is further configured to receive a price range in which the custom furniture is to cost to purchase, and wherein executing a simulation further includes executing a simulation to define the at least one structural member of the at least one piece of custom furniture that further satisfies the price range in which the custom furniture is to cost.

15. The method according to claim 13, wherein displaying a graphical representation of the at least one piece of custom furniture includes displaying a transparent or translucent graphical model of the at least one piece of custom furniture on an electronic display.

16. The method according to claim 13, wherein displaying a graphical representation further includes displaying measurements on the at least one piece of custom furniture.

17. The method according to claim 1, further comprising:
receiving additional information or change information via the user interface with respect to the at least one physical parameter of the custom furniture;
causing the artificial intelligence engine to revise the at least one piece of the custom furniture in response to submitting a new prompt or update to the previous prompt; and
determining whether the at least one structural member of the at least one piece of custom furniture has changed, and if so, executing the simulation to re-define the at least one structural member of the at least one piece of custom furniture that satisfies the additional information or change information with respect to the at least one physical parameter of the custom furniture, otherwise, not executing the simulation.

18. The method according to claim 1, further comprising:
in response to determining size of a user who will use the furniture, causing the artificial intelligence engine to generate the at least one piece of the custom furniture in response to submitting a prompt include at least one physical parameter of the user.

19. The method according to claim 1, further comprising automatically determining the size of the user in response to capturing an image of the user.

20. The method according to claim 1, further comprising automatically generating one or more lists of materials and/or parts that are to be used in producing the custom furniture.

21. The method according to claim 1, further comprising automatically generating an assembly guide for assembling the custom furniture.

22. The method according to claim 1, further comprising communicating the one or more lists to suppliers and manufacturers.
